(19) United States
(12) Patent Application Publication
(10) Pub. No.: US 2009/0057721 A1
(43) Pub. Date: Mar. 5, 2009

(54) SEMICONDUCTOR DEVICE, EPITAXIAL WAFER, AND METHOD OF MANUFACTURING THE SAME

(75) Inventors: Kouhei Miura, Osaka (JP); Yasuhiro Iguchi, Osaka (JP)

Correspondence Address: FISH & RICHARDSON P.C., P.O. BOX 1022, MINNEAPOLIS, MN, 55440-1022, US

(73) Assignee: Sumitomo Electric Industries, Ltd., Osaka (JP)

(21) Appl. No.: 12/202,460

(22) Filed: Sep. 2, 2008

(30) Foreign Application Priority Data
Sep. 3, 2007 (JP) 2007-227648

(51) Int. Cl. H01L 21/20; H01L 29/20

(52) U.S. Cl. 257/201; 438/483; 257/615; 257/E29.089; 257/E21.131

(57) ABSTRACT

A manufacturing method and a semiconductor device produced by the method are provided, in which the semiconductor device can easily be manufactured while the hydrogen concentration is decreased. An N-containing InGaAs layer 3 is grown on an InP substrate by the MBE method, and thereafter a heat treatment is provided at a temperature in the range of 600° C. or more and less than 800° C., whereby the average hydrogen concentration of the N-containing InGaAs layer 3 is made equal to or 2×10¹⁷/cm³ or less than.

### BACKGROUND OF THE INVENTION

1. Field of the Invention

The present invention relates to a semiconductor device, an epitaxial wafer, and the method of manufacturing the same. More specifically, the invention relates to a semiconductor device or an epitaxial wafer which has an N-containing InGaAs-based layer, and a method of manufacturing the same.

2. Description of the Background Art

It is known that the degradation of crystal quality is caused by mixing of high concentration of hydrogen into GaNAs and GaInNAs including In-composition of 35% or less in III-group elements that have been grown on a Gabs substrate by the OMVPE method. Therefore, in the method proposed in Japanese Patent Application Publication No. H11-274083 (Patent document 1), the hydrogen concentration is reduced by performing heat treatment for dehydrogenation after growing the above-mentioned semiconductor layer on a GaAs substrate by the OMVPE method. According to this method, it is possible to reduce the hydrogen concentration in the semiconductor layer to 5×10¹⁸/cm³ or less by heating, at 800° C. or more and 1100° C. or less, the GaAs substrate that includes the above-mentioned semiconductor layer. Also, it is disclosed that, although the hydrogen concentration in the above semiconductor layer is not reduced, the bonding of the hydrogen impurities and nitrogen in the semiconductor layer can be cut by heating at 500° C. or more and less than 800° C.

Since a GaInNAs layer grown on the InP substrate has a bandgap corresponding to the near-infrared range, wide ranges of researches for development have been promoted, from the basics about the crystal quality and the like to the application of various sensors, etc., in order to use the GaInNAs layer for various kinds of measurements regarding the living body, and communications, etc. In order to receive light of near-infrared range with high sensitivity, it is important that the GaInNAs have good crystal quality, and particularly when it is used for a photodiode of the near-infrared range, it is important to obtain a low-carrier density and high-purity GaInNAs crystals from the view point of restraining a dark current. The hydrogen concentration must be reduced because, if hydrogen mixes with GaInNAs, defects that play a role of donors are formed, whereby the density of lattice defects is increased, resulting in degradation of the crystal quality.

When scrupulously following the method disclosed in Japanese Patent Application Publication No. H11-274083, it is necessary to heat at 800° C. or more and 1100° C. or less so as to reduce hydrogen in the GaInNAs. However, if P-containing compound semiconductors, such as an InP substrate and the like, are heated at such a high temperature as mentioned above, dephosphorization phenomenon occurs, resulting in malfunction of the semiconductor devices including these P elements. In addition to such dephosphorization, other problems will occur, making it difficult to form semiconductor devices such as a photodiode. The GaInNAs having lattice matching with InP has a significant potential since it exhibits continuous optical sensitivity capable of receiving light of not only the near infrared range but also the visible range. Therefore, it is desired to develop a manufacturing method in which a semiconductor stacked structure such as a photodiode can easily be obtained while the hydrogen concentration is decreased.

### SUMMARY OF THE INVENTION

The object of the present invention is to provide a manufacturing method by which a semiconductor device and an epitaxial wafer can easily be manufactured while the hydrogen concentration is decreased, and also to provide a semiconductor device and an epitaxial wafer which are produced by the method.

The method of manufacturing a semiconductor device or an epitaxial wafer according to the present invention is a method of manufacturing a semiconductor device which includes a stacked structure of compound semiconductors. In this manufacturing method, a Ga₁₋ₓInₓN_{y}As_{1-y-x}Sbₓ layer (0.4≦x≦0.8, 0<y≦0.1, 0≦z≦0.1) or a Ga₁₋ₓInₓN_{y}As_{1-y-z}P_{z} layer (0.4≦x≦0.8, 0<y≦0.1, 0≦z≦0.1) is epitaxially grown on an InP substrate by a molecular beam epitaxy (MBE) method, and thereafter a heat treatment is provided at a temperature in the range of 600° C. or more and less than 800° C., wherein the average hydrogen concentration of the Ga_{1-z}InₓN_{y}As_{1-y-z}Sb_{z} layer or the Ga_{1-z}InₓN_{y}As_{1-y-z}Sb_{z} layer is made equal to or less than 2×10¹⁷/cm³. Hereinafter, the Ga_{1-z}InₓN_{y}As_{1-y-z}Sb_{z} layer (0.4≦x≦0.8, 0<y≦0.1, 0≦z≦0.1) or the Ga₁₋ₓInₓN_{y}As_{1-y-z}P_{z} layer (0.4≦x≦0.8, 0<y≦0.1, 0≦z≦0.1) is referred to as an N-containing InGaAs-based layer.

According to the above-mentioned method, since the N-containing InGaAs-based layer is formed by the MBE method in which a raw material that does not contain hydrogen (H) in the chemical formula thereof is used, the hydrogen is limited to the thickness range at an early stage of forming the N-containing InGaAa-based layer, and accordingly a high-concentration hydrogen layer is formed only in a narrow thickness range limited from the bottom face of the N-containing InGaAa-based layer. Hereinafter, the MBE method is assumed to use a raw material that does not contain H in the chemical formula. In the upper side above the high-concentration hydrogen layer, the hydrogen concentration can be suppressed to be lower. Therefore, by a heat treatment of such a low temperature as in the range of 600° C. or more to less than 800° C., the hydrogen can be reduced to a low level that will not cause a significant problem. As a result, both the hydrogen peak value of the high-concentration hydrogen layer and the hydrogen concentration of substantially flat distribution in a layer upper than the high-concentration hydrogen layer can be decreased by the heat treatment, and accordingly the average hydrogen concentration of the N-containing InGaAs-based layer can be decreased. Therefore, the crystal quality of the N-containing InGaAs-based layer can be enhanced, and consequently a high quality semiconductor stacked structure or semiconductor device can easily be manufactured. Here, the ground of the N-containing InGaAs-based layer corresponds to a buffer layer that is epitaxially formed in contact with an InP substrate; however, it may be a ground other than the buffer layer, that is, it may be an InP substrate, for example.

When the N-containing InGaAs-based layer is firmed by the MBE method, the hydrogen concentration becomes higher in the thickness range formed at an early stage of film formation and becomes lower in the upper portion of the N-containing InGaAs-based layer. This mechanism will be explained later in the description of embodiments of the invention. The maximum of the hydrogen concentration peak value in the high-concentration hydrogen layer formed by epitaxial growth according to the MBE method is, for example, 2×10¹⁸/cm³.

With the above-mentioned heat treatment, the high-concentration hydrogen layer having a hydrogen concentration peak value of 2×10¹⁸/cm³ or less can be limited to a range of 0.5 μm or less in thickness, within the Ga₁₋ₓInₓN_{y}As_{1-y-z}Sb_{z} layer or the Ga₁₋ₓInₓN_{y}As_{1-y-z}P_{z} layer, from the interface between the ground and the Ga₁₋ₓInₓN_{y}As_{1-y-z}Sb_{z} layer or the Ga₁₋ₓInₓN_{y}As_{1-y-z}P_{z} layer. This makes it possible to easily obtain a high-quality semiconductor device including the N-containing InGaAs-based layer.

Prior to the above-mentioned heat treatment, a passivation film can be formed on the rear surface of an InP substrate so that the dephosphorization may not occur at the rear surface of the InP substrate. According to this method, the dephosphorization from the rear surface of the InP substrate at the time of the above-mentioned heat treatment for dehydrogenation can be prevented, either before another film is formed on the previously formed N-containing InGaAs layer, or after a window layer that does not contain P. e.g., an InAlAs window layer, has been formed on the N-containing InGaAs layer. The passivation film formed at the rear surface of the InP substrate is made of SiN, SiON, SiO₂, etc., and is removed at the time of forming an electrode.

When the heat treatment is performed after the InP window layer has been formed on the above-mentioned epitaxially grown Ga₁₋ₓInₓN_{y}As_{1-y-z}Sb_{z} layer or Ga₁₋ₓInₓN_{y}As_{1-y-z}P_{z} layer, a P-containing gas can be flowed into the atmosphere. In this method, the N-containing InGaAs-based layer is formed and the InP window layer is formed thereon, and subsequently the heat treatment for dehydrogenation is performed. However, the P-containing layer exists in the InP substrate and the InP window layer, and the passivation film on the InP window layer cannot be removed later. Therefore, the dephosphorization can be prevented by flowing a P-containing gas and enhancing the P partial pressure of the heat-treatment atmosphere.

The semiconductor device or the epitaxial wafer of the present invention has an InP substrate and the N-containing InGaAs-based layer formed by epitaxial growth on the InP substrate. And, its feature is that the average hydrogen concentration of the N-containing InGaAa-based layer is equal to 2×10¹⁷/cm³ or less.

Another aspect of the semiconductor device or the epitaxial wafer of the present invention, which comprises the InP substrate and the N-containing InGaAs-based layer formed by epitaxial growth on the InP substrate, is characterized in that the high-concentration hydrogen layer having a hydrogen concentration peak value of 2×10¹⁸/cm³ or less is limited to a range of 0.5 μm or less in thickness, within the N-containing InGaAa-based layer, from the interface between the ground and the N-containing InGaAs-based layer.

In both of the above-mentioned semiconductor device or epitaxial wafer and another aspect of the semiconductor device or epitaxial wafer according to the present invention, the high-concentration hydrogen layer is locally situated and also the concentration of hydrogen is reduced to a level that does not cause a problem, and accordingly the crystal quality of the N-containing InGaAs-based layer is higher and moreover the crystal quality of the entire semiconductor device is improved Consequently, a semiconductor device having high sensitivity can easily be manufactured, for example.

It is possible to provide a buffer layer of n-type semiconductor between the above-mentioned InP substrate and the N-containing InGaAs-based layer. With this, an N-containing InGaAs-based layer having excellent crystal quality can be obtained.

The carrier concentration of the above-mentioned buffer layer can be made equal to 1×10¹⁶/cm³ or more. Therefore, it is possible to make the carrier concentration of the buffer layer to be an ideal one for forming a photodiode.

t is possible to make a photodiode of the above-mentioned semiconductor device. With this, it is possible to obtain a photodetector having high sensitivity for the near-infrared range and a shortwave length range shorter than that.

According to the present invention, a high quality semiconductor device or epitaxial wafer can easily be obtained while the hydrogen concentration is decreased.

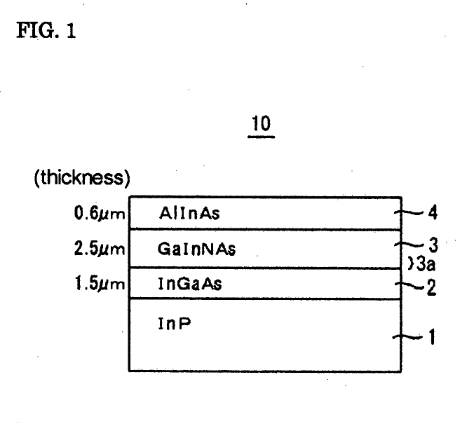

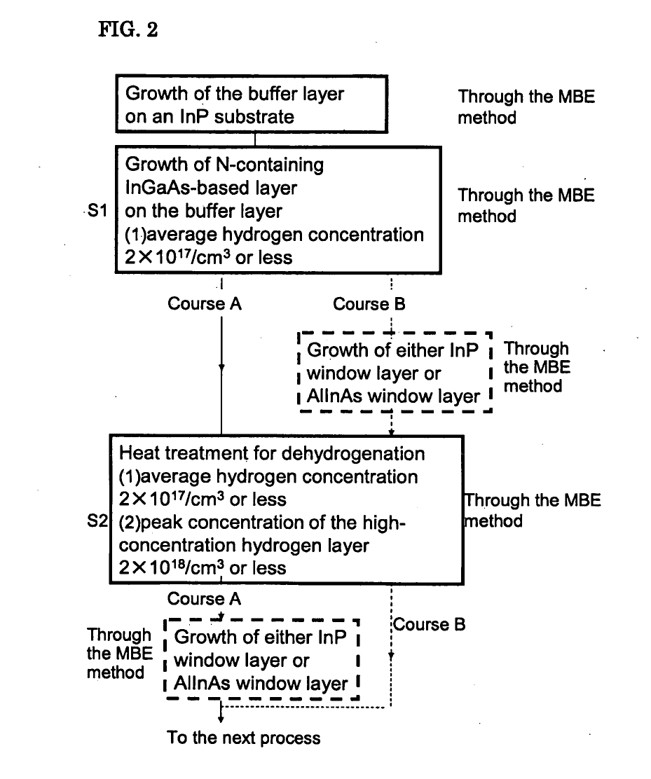

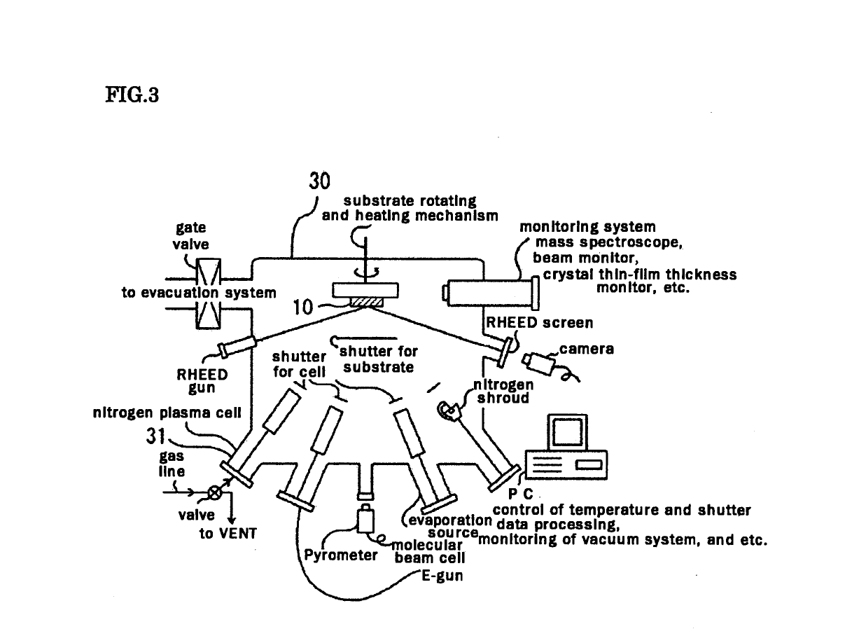

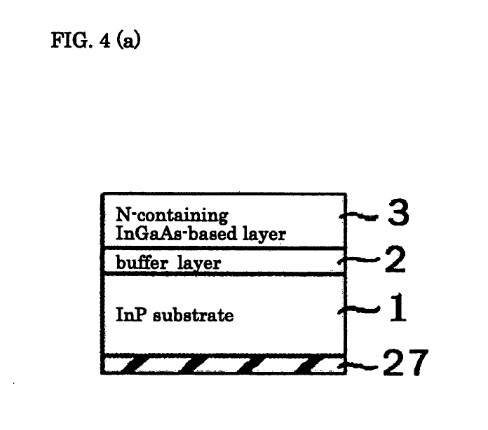

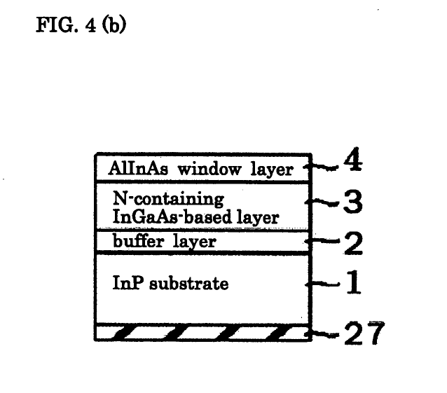

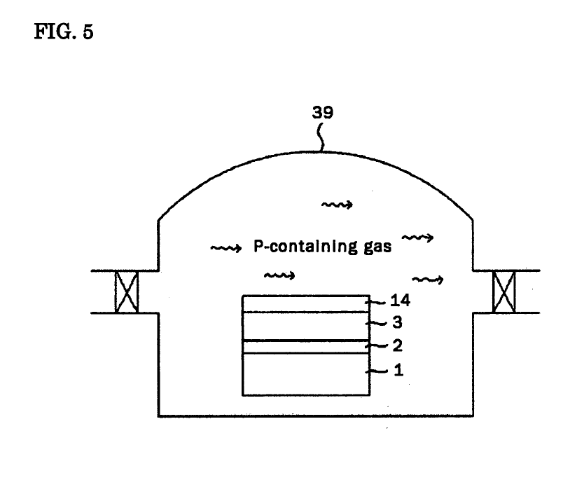

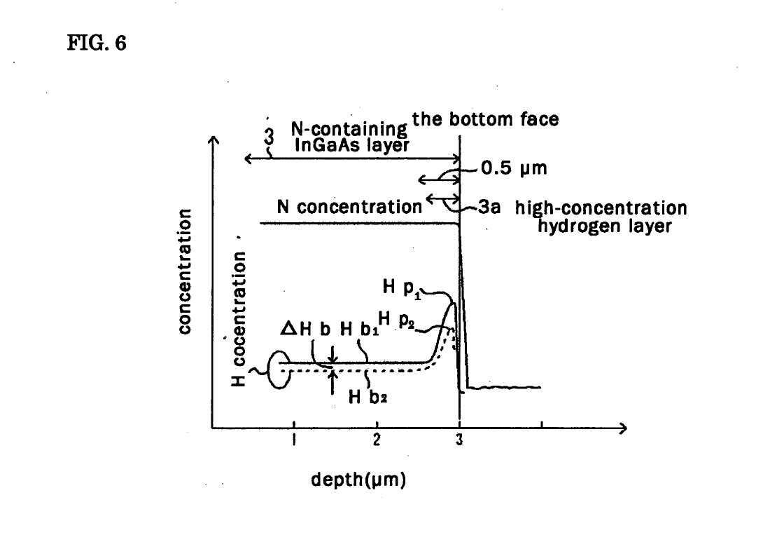

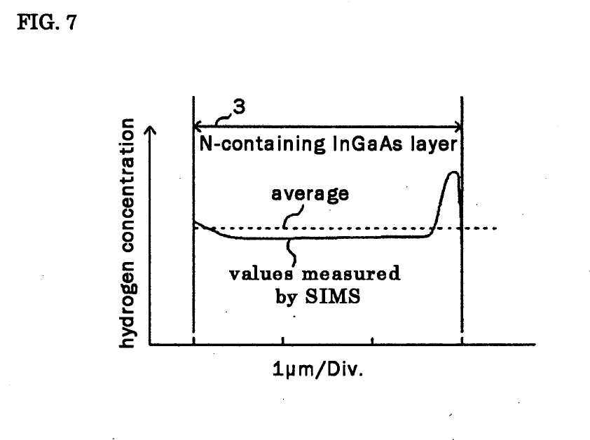

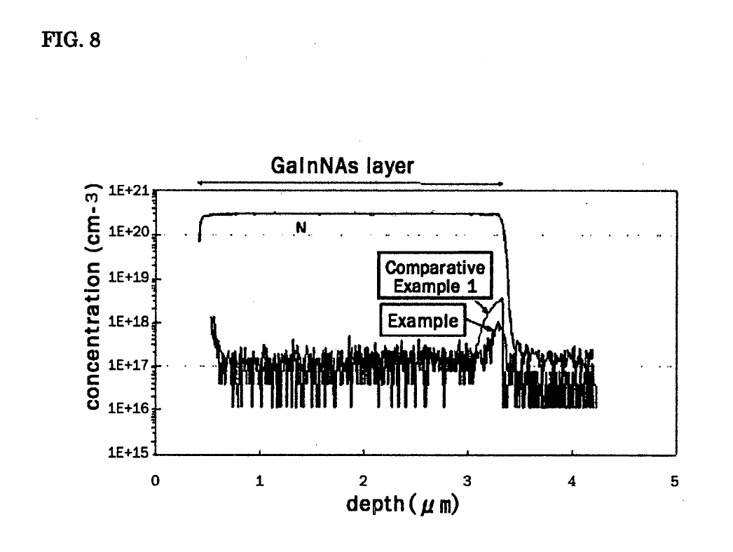

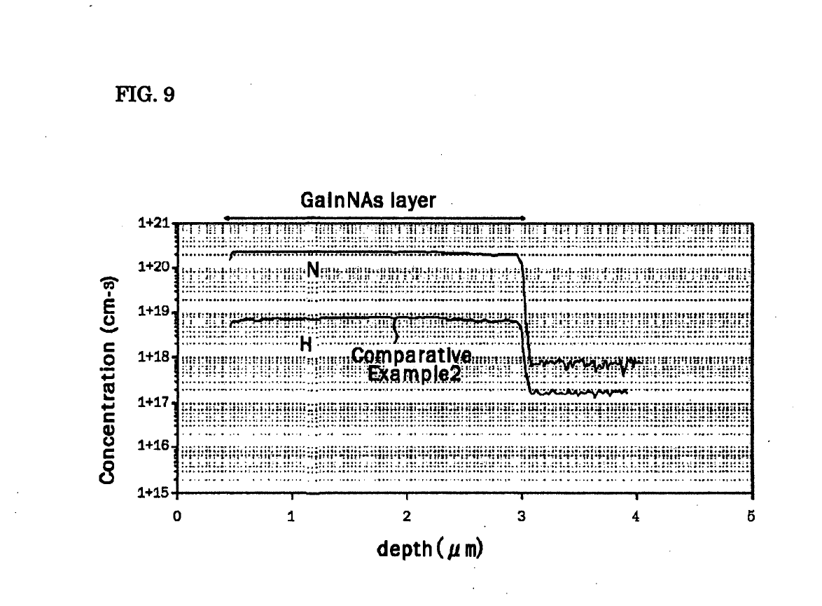

### BRIEF DESCRIPTION OF THE DRAWINGS

[FIG. 1] A sectional view showing a stacked structure for a photodiode according to an embodiment of the present invention.

[FIG. 2] A diagram illustrating processes of manufacturing the photodiode of FIG. 1.

[FIG. 3] A schematic diagram showing an example of equipment for forming a film by the MBE method.

[FIG. 4(a)] A schematic diagram to explain forming a passivation film on the rear surface of an InP substrate at the time of the dehydrogenation process which is performed before a window layer is formed.

[FIG. 4(b)] A schematic drawing to explain forming a passivation film on the rear surface of an InP substrate at the time of the dehydrogenation process which is performed after an AlInAs window layer has been formed.

[FIG. 5] A schematic diagram illustrating a way of the dehydrogenation process performed after an InP window layer has been formed.

[FIG. 6] A schematic diagram illustrating a state of the hydrogen distribution in the thickness direction existing before and after the dehydrogenation process.

[FIG. 7] A schematic diagram for illustrating a method of seeking the average hydrogen concentration of the N-containing InGaAs-based layer.

[FIG. 8] A graph showing the distribution of the hydrogen concentration in the thickness direction in the Example of the present invention.

[FIG. 9] A graph showing the distribution of the hydrogen concentration in the thickness direction in Comparative Example 2 in the Example.

### DETAILED DESCRIPTION OF THE INVENTION

### Embodiment 1

FIG. 1 is a sectional view showing a stacked structure 10 of a semiconductor device in Embodiment 1 of the present invention. The stacked structure 10 is formed of compound semiconductor layers as described in the following. The epitaxial wafer, which is regarded as an intermediate product for forming a semiconductor device including the stacked structure 10, is sold as such on the market. Hereinafter, the term “semiconductor device” used in the description of a compound semiconductor layer includes an epitaxial wafer. Stacked structure 10: (InP substrate 1/InGaAs buffer layer 2/GaInNAs receiving layer 3/AlInAs window layer 4)

The thickness of each layer is roughly as follows: InGaAs buffer layer 2 is about 1 μm to 2 μm; GaInNAs light-receiving layer 3, which is an N-containing InGaAs-based layer, is 2 μm to 3 μm; and AlInAs window layer 4 is 0.5 μm to 1.5 μm. In the case where a semiconductor photodetector is a photodiode, a mask pattern is provided on the AlInAs window layer 4, and p-type impurities are introduced through the AlInAs window layer 4 so as to reach the GaInNAs light-receiving layer 3 so that a pn-junction or a pin-junction is formed. Thereafter, a p-part electrode is formed on the p-type region of the AlInAs window layer 4, and an n-part electrode for ohmic contact is formed on an InP substrate 1 or an InGaAs buffer layer 2.

In the GaInNAs light-receiving layer 3, a high-concentration hydrogen layer 3a that has a hydrogen concentration peak exists in a range within 0.5 μm or less in thickness from the bottom face of the GaInNAs light-receiving layer 3 or from the interface with the InGaAs buffer layer 2. Of course, hydrogen is contained in the GaInNAs light-receiving layer 3 that lies on the upper side than the high-concentration hydrogen layer 3a; however, the concentration of the hydrogen is lower by one digit, and the concentration distribution is substantial flat in the thickness direction. The above-mentioned peak value of the hydrogen concentration differs depending on a product; however the high-concentration hydrogen layer 3a and the above-mentioned substantially flat concentration distribution can clearly be distinguished. Therefore, it is easy to identify the high-concentration hydrogen layer 3a which is within a thickness range of 0.5 μm or less from the bottom face.

Next, the method of manufacturing a semiconductor device according to an embodiment of the present invention will be described in reference to FIG. 2. First, an InGaAs buffer layer 2 is epitaxially grown on an InP substrate 1. Next, a N-containing InGaAs-based layer 3 is epitaxially grown by the MBE method on the InGaAs buffer layer 2. FIG. 3 is a schematic diagram showing an example of equipment for forming a film by the MBE method. The stacked structure 10 which includes the InP substrate 1 is installed in a substrate rotating and heating mechanism so that it is heated and put in a ratating condition. For forming film layers, molecular beam cells (E-gun) of vaporization sources are arranged corresponding to elements which constitute layers, and in the case of the InGaAs layer, molecular beam cells which respectively emit molecular beams of In, Ga and As are arranged. In FIG. 3, three molecular beam cells including a gas cell 31 are shown and some cells are omitted.

To control chemical composition and speed for forming a film, the opening and shutting operation of a cell shutter and a substrate shutter is adjusted using an attached computer. The temperature of a substrate and the like are measured by a pyrometer. For the purpose of monitoring by reflection high electron energy diffraction (RHEED), a RHEED electron gun is arranged so that an electron may be incident on a stacked structure 10 at a shallow incident angle, and a fluorescence screen (RHEED screen) for obtaining the diffraction image and a camera for taking the diffraction image are provided at a position in the direction of diffraction. The RHEED is used for evaluating the crystal quality of the stacked structure 10 and grasping each elemental process of forming a film, and so on. Also, a monitoring system, which includes a mass spectroscope, a beam monitor, a crystal thin-film thickness monitor, etc., is installed. Of the molecular beams and the like, those which have not been incorporated into the stacked structure 10 are exhausted into an evacuation system. Also, the liquid nitrogen shroud is used for adsorbing impurities which are generated as a result of collision of molecular beams. The inside of the equipment for forming a film communicates with the evacuation system through a gate valve.

When the N-containing InGaAs-based layer 3 is formed, a nitrogen gas is supplied to a gas line to introduce nitrogen (N) into the N-containing InGaAs-based layer, and the nitrogen is excited in a nitrogen plasma cell 31 so that the excited nitrogen molecular beams may be irradiated to the stacked structure 10. When the nitrogen gas and other raw materials are excited in the nitrogen plasma cell 31 and other cells, the moisture existing in the raw material gas or the vapor floating in the equipment is excited by each cell, and is carried from each cell to the stacked structure 10 so as to mix into the crystal layer. By exhausting the vapor at an early stage of growth of N-containing InGaAs crystals, the mixing of hydrogen into the N-containing InGaAs-based layer 3 can be limited to the early stage of growth of the N-containing InGaAs-based layer 3. That is, it can be limited to a thickness range of 0.5 μm or less from the bottom face of the N-containing InGaAs layer having a film thickness of 2 μm to 3 μm. The operation to achieve the above-mentioned hydrogen concentration distribution will be explained later.

The above-mentioned high-concentration hydrogen layer 3a generally has a hydrogen-concentration depth profile of mountain-like shape including a peak. It is possible to limit the average hydrogen concentration of the entire N-containing InGaAs layer 3 to 2×10¹⁷/cm³ or less while performing the dehydrogenation heat treatment at a low temperature in the range of 600° C. or more to less than 800° C. The above description is an explanation about the process of Step S1 shown in FIG. 2. Next, the processes subsequent to Step S1 will be explained.

In FIG. 2, there are two courses, A and B, after the process of Step S1. In the case of Course A, the heat treatment for dehydrogenation is done without providing a window layer 4 after forming the N-containing InGaAs-based layer 3. At the time of this dehydrogenation process, the dephosphorization phenomenon of the InP substrate 1 must be prevented. Therefore, in Course A, although it is omitted in FIG. 2, a passivation film 27 is provided, as shown in FIG. 4(a), on the rear surface of the InP substrate 1 before the dehydrogenation process. The passivation film 27 may be made using SiN, SiON, SiO₂, or the like. With this passivation film 27, the dehydrogenation process can be performed in a usual atmosphere, e.g., an atmosphere of nitrogen gas, without paying much consideration to the P partial pressure and the like in the atmosphere of the dehydrogenation process. The passivation film 27 is removed after the dehydrogenation process, e.g., at the time of forming an n-part electrode on the rear surface of the InP substrate 1. In the case of Course A, when manufacturing a photodiode, a window layer 4 can be formed of InP, AlInAs, or the like after the dehydrogenation process of Step S2 is performed.

Also, in the case of Course B, the window layer 4 is formed with AlInAs on the N-containing InGaAs-based layer 3. In FIG. 4(b), a window layer 4 made of AlInAs is shown; however, it may be formed with any of InP, AlInAs, and InGaAs. In this case, if the window layer 4 is made of AlInAs, the upper surface exposed to the atmosphere at the time of dehydrogenation process is not a substance including P; therefore, the dehydrogenation process can be performed only by providing the passivation film 27 on the rear surface of the InP substrate 1 as shown in FIG. 4 (b).

In Course B, if InP is used for the window layer 4, then, the InP that contains P exists at the top face and the bottom face. When manufacturing a photodiode, it is necessary to make the window layer 4 thin, since p-type impurities are injected by diffusion into the N-containing InGaAs-based layer 3 through the window layer 4. Consequently, it becomes difficult to secure a flat surface after removing a passivation film formed for the dehydrogenation process. Therefore, in the case where InP is used for the window layer 4 in Course B, the dephosphorization of P from InP which constitutes the substrate 1 and the window layer 4 must be prevented by enhancing the P partial pressure of the atmosphere by flowing a P-containing gas such as phosphine (PH₃) in a heat-treatment chamber 39 as shown in FIG. 5, or by enclosing with solid phosphorus, or the like. In this case, obviously it is unnecessary to provide a passivation film on the rear surface of the InP substrate 1.

After the dehydrogenation process of Step S2 is performed, in Courses A and B, the hydrogen concentration peak value of the high-concentration hydrogen layer 3a becomes 2×10¹⁸/cm³ or less, and the average hydrogen concentration of N-containing InGaAs-based layer 3 becomes 2×10¹⁷/cm³ or less. As a result, the N-containing InGaAs-based layer 3 having low defect density can be obtained, and accordingly it is possible to easily obtain a semiconductor device or a photodiode in which the dark current is restrained and the sensitivity is excellent.

FIG. 6 is a diagram for illustrating variations of the hydrogen concentration distribution (distribution in the thickness direction) before and after Step S2. In FIG. 6, nitrogen concentration distribution is shown; the nitrogen concentration distribution does not change due to the dehydrogenation process. The N-containing InGaAa-based layer 3 is formed by the MBE method, and prior to the dehydrogenation process, the peak value Hp1 of the high-concentration hydrogen layer 3a is about 4×10¹⁸/cm³, for example, as shown later in Example. Also, the hydrogen concentration value Hb1 of the flat part on the upper side of the high-concentration hydrogen layer 3a is from about 1.5×10¹⁷/cm³ to about 2×10¹⁷/cm³. In contrast, after Step S2 (dehydrogenation process), the peak value Hp2 becomes about 1×10¹⁸/cm³, and the hydrogen concentration value Hb2 of the flat part becomes about 1×10¹⁷/cm³. The hydrogen concentration difference ΔHb observed before and after the heat-treatment is from about 0.5×10¹⁷/cm³ to about 1×10¹⁷/cm³ in the flat concentration part.

According to the above, because of hydrogen decrease in both of the base part and the high-concentration hydrogen layer, the average hydrogen concentration of the N-containing InGaAs-based layer 3 can surely be made lower to 2×10¹⁷/cm³ or less. The average hydrogen concentration of the N-containing InGaAs-based layer 3 can be obtained by averaging the whole hydrogen concentration distribution including the high-concentration hydrogen layer 3a according to the thickness of the N-containing InGaAs-based layer 3 as shown in FIG. 7. The calculation for obtaining the average value can easily be done using a personal computer or the like.

Next, a method of controlling the thickness of a high-concentration hydrogen layer 3a is explained In the case where the high-concentration hydrogen layer 3a is grown by the MBE method using raw materials which do not include hydrogen, the hydrogen concentration becomes high only in the thickness range which corresponds to an early stage of growth, and the layer upper than that has a flat depth profile of low hydrogen concentration. Therefore, the thickness of high-concentration hydrogen layer 3a and the concentration peak value can be controlled by subjecting the early stage growth to the following operation.
(1) After a ground buffer layer for an N-containing InGaAs-based light-receiving layer is formed, each cell to form the N-containing InGaAs-based light-receiving layer is put into operation, and molecular beams emitted from each cell is received with a substrate shutter for a given time. Consequently, the molecular beams emitted at the early stage of growth are interrupted by the substrate shutter and do not reach the stacked structure 10 including the ground buffer layer. By making the substrate shutter open after the elapse of the given time, the molecular beam having low hydrogen concentration and corresponding to the flat concentration part can be made to contribute from the first growth. However, this operation has the drawback that the density of crystal defect increases since the ground buffer layer suffers from unevenness caused in the surface as the time lapses after it is formed.
(2) The rate of growing the N-containing InGaAs-based light-receiving layer is made slower at an early stage. In the operation of (2), basically the growth is done while the shutter for each element to constitute the N-containing InGaAs-based light-receiving layer is subjected to opening and shutting operation at a short time pitch. And, at the early stage of growth, the growth rate is made slower as much as possible by coordinating the respective cells such that the temporal ratio of the closed condition to the open condition is made larger. Thus, most of the part which contain hydrogen with high concentration at the early stage of growth is interrupted by each cell shutter, and the thickness of the high-concentration hydrogen layer 3a is made thinner. With this operation (2), it is possible to control the thickness of the high-concentration hydrogen layer 3a.

Also, the hydrogen concentration of the above-mentioned high-concentration hydrogen layer 3a and the flat concentration part can be made lower by using a high quality raw material containing less impurities and setting the baking temperature of the MBE growth chamber at 100° C. or more. The hydrogen concentration distribution of the present invention can be achieved by the baking temperature of 100 ° C. or more, the removal of impurities in the raw material and the ratio of the opening and shutting in the short time pitch of the cell shutter as described above. The above-mentioned operation can satisfictorily reproduce the average hydrogen concentration, the thickness distribution range of the high-concentration hydrogen layer, and the hydrogen concentration peak value.

As a result, a high-quality semiconductor stacked structure or semiconductor device can easily be manufactured by improving the crystal quality of the N-containing InGaAs-based layer. The reduction of the above-mentioned hydrogen concentration is achieved by a heat treatment performed at a low temperature in the range of 600° C. to less than 800° C., and does not causes irregularities to the semiconductor device or the photodiode.

### EXAMPLE

Next, an explanation will be made about semiconductor devices prepared as a photodiode in Example of the present invention and Comparative Example and the results of depth profiling of hydrogen thereof using a secondary ion mass spectroscopy (SIMS). The stacked structure 10 used in the photodiode has the composition shown in FIG. 1.

### Example of the Present Invention

Each layer of the stacked structure 10 is firmed by the MBE method. First, an InGaAs buffer layer 2 was formed in a thickness of 1.5 μm by epitaxial growth on an InP substrate 1. When the InGaAs buffer layer 2 was grown, Si was doped to make an n-conductivity type having a carrier concentration of 5×10¹⁶/cm³. Next, a GaInNAs light-receiving layer 3 was formed in a thickness of 2.5 μm by epitaxial growth. The temperature for the growth was 500° C. The composition of III-group element was such that Ga was 46% and In was 54%. As for the V-group element, As was 98.5%, and the balance was N. Doping was not performed. Next, an AlInAs window layer 4 was formed by epitaxial growth. When the GaInNAs receiving layer 3 was grown, the raw materials and growth conditions were chosen so as to limit the thickness of the high-concentration hydrogen layer 3a to a range of 0.5 μm or less from the bottom face. The E-group elements were such that In was 52%, and the balance was Al. Subsequently, dehydrogenation heat treatment was performed for one minute at 660° C. by rapid thermal annealing (ETA).

As shown in FIG. 1, the above-mentioned stacked structure was composed of InP substrate 1, Si-doped InGaAs buffer layer 2, GaInNAs light-receiving layer 3 (the high-concentration hydrogen layer 3a was limited to the thickness range of 0.5 μm or less from the bottom face), and AlInAs window layer 4).

### Comparative Example 1

In Comparative Example 1, a stacked structure was prepared by the MBE method in the same manner as in Example of the present invention except that the InGaAs buffer layer 2 had a thickness of 0.15 μm and had no doping and further except that no heat treatment for dehydrogenation was done to the stacked structure made by the MBE method, which was a fundamental difference from the Example of the present invention.

### Comparative Example 2

In Comparative Example 2, the stacked structure was formed by the organometalic vapor phase epitaxy (OMVPE) method in the same manner as Example of the present invention except that the stacked structure was not subjected to the dehydrogenation heat treatment.

With respect to the above-mentioned stacked structures, the hydrogen and nitrogen distributions in the thickness (depth) direction were measured by SIMS and the results of the measurement are shown in FIGS. 8 and 9. In Comparative Example 1 shown in FIG. 8, the peak value of the high-concentration hydrogen layer is about 4×10¹⁸/cm³. Also, in the GaInNAs layer formed by the OMVPE method in Comparative Example 2, as shown in FIG. 9, the hydrogen concentration is about 7×10¹⁸/cm³ to 9×10¹⁸/cm³ over the whole thickness. In comparison with this, in Example of the present invention, as shown in FIG. 8, the peak value of the hydrogen concentration in the high-concentration hydrogen layer becomes about 1×10¹⁸/cm³. As a result, the average hydrogen concentration in the GaInNAs layer can be made equal to or less than 2×10¹⁷/cm³.

As Patent Document 1 discloses, in the past, it has been considered as impossible to release hydrogen from the crystal without setting the temperature for the dehydrogenation process to fall in a range of 800° C. to 1000° C. However, it holds true in the case where the GaInNAs layer is grown by OMVPE as shown in the above-mentioned Comparative Example 2, which is the case where the hydrogen quantity is very high. According to the MBE method, in addition to limiting the peak value of the hydrogen concentration, the hydrogen concentration layer can be limited to a thickness within a range of 0.5 μm or less from the bottom face, and in the layer upper than that the peak value of the hydrogen concentration can be limited to such a small value as one to several tens as compared with a value in the case of the OMVPE method. This is conceived to be the reason why the desired sufficiently low average concentration of hydrogen was achieved by dehydrogenation process performed at a low temperature of 600° C. to less than 800° C.

In the above Example, the explanation was given with respect to a photodiode; however, the semiconductor device of the present invention is not limited to the photodiode, and may be any device, such as a various kind of sensor, imaging device, emitting light device, or the like, provided that it satisfies the elements of the present invention. That is, it may be used for any product that has the N-containing InGaAs-based layer provided on an InP substrate and satisfies the depth profile of hydrogen.

In the above, preferred embodiments and examples of the present invention were described; however, they are simply exemplary. The scope of the present invention is not limited to them, but is specified by the claims, and includes any modification that is within the scope of, or equivalent to, any of the claims.

What is claimed is:

1. A method of manufacturing a semiconductor device, comprising the steps of:
epitaxially growing a Ga₁₋ₓInₓN_{y}As_{1-y-z}Sb_{z} layer (0.4≦x≦0.8, 0<y≦0.1, 0≦z≦0.1) or a Ga₁₋ₓInₓN_{y}As_{1-y-z}P_{z} layer (0.4≦x≦0.8, 0<y≦0.1, 0≦z≦0.1) on an InP substrate by a molecular beam epitaxy (MBE) method; and
providing a heat treatment at a temperature in the range of 600° C. or more and less than 800° C. after the said step of epitaxial growth, wherein the average hydrogen concentration of the Ga₁₋ₓInₓN_{y}As_{1-y-z}Sb_{z} layer or the Ga₁₋ₓInₓN_{y}As_{1-y-z}P_{z} layer is made equal to or less than 2×10¹⁷/cm³.

2. A method of manufacturing a semiconductor device according to claim 1, wherein by the said heat treatment, the high-concentration hydrogen layer having a hydrogen concentration peak value of 2×10¹⁸/cm³ or less is limited to a range of 0.5 μm or less in thickness, within the Ga₁₋ₓInₓN_{y}As_{1-y-z}Sb_{z} layer or the Ga₁₋ₓInₓN_{y}As_{1-y-z}P_{z} layer, from the interface between a ground and the Ga₁₋ₓInₓN_{y}As_{1-y-z}Sbₓ layer or the Ga₁₋ₓInₓN_{y}As_{1-y-z}P_{z} layer.

3. A method of manufacturing a semiconductor device according to claim 1, wherein prior to the said heat treatment, a passivation film is formed on the rear surface of an InP substrate so as to prevent dephosphorization from occurring at the rear surface of the InP substrate.

4. A method of manufacturing a semiconductor device according to claim 1, wherein a P-containing gas is flowed into the atmosphere when the said heat treatment is performed after the InP window layer has been formed on the epitaxially grown Ga₁₋ₓInₓN_{y}As_{1-y-z}Sb_{z} layer or Ga₁₋ₓInₓN_{y}As_{1-y-z}P_{z} layer.

5. A semiconductor device comprising an InP substrate and a Ga₁₋ₓInₓN_{y}As_{1-y-z}Sb_{z} layer (0.4≦x≦0.8, 0<y≦0.1, 0≦z≦0.1) or a Ga₁₋ₓInₓN_{y}As_{1-y-z}Sb_{z} layer (0.4≦x≦0.8, 0<y≦0.1, 0≦z≦0.1) formed by epitaxial growth on the InP substrate, wherein the average hydrogen concentration of the Ga₁₋ₓInₓN_{y}As_{1-y-z}Sb_{z} layer or the Ga₁₋ₓInₓN_{y}As_{1-y-z}P_{z} layer is equal to 2×10¹⁷/cm³ or less.

6. A semiconductor device comprising an InP substrate and a Ga₁₋ₓInₓN_{y}As_{1-y-z}Sbₓ layer (0.4≦x≦0.8, 0<y≦0.1, 0≦z≦0.1) or a Ga₁₋ₓInₓN_{y}As_{1-y-z}Sbₓ layer (0.4≦x≦0.8, 0<y≦0.1, 0≦z≦0.1) formed by epitaxial growth on the InP substrate, wherein a high-concentration hydrogen layer having a hydrogen concentration peak value of 2×10¹⁸/cm³ or less is provided within a range of 0.5 μm or less in thickness in the Ga₁₋ₓInₓN_{y}As_{1-y-z}Sb_{z} layer or the Ga₁₋ₓInₓN_{y}As_{1-y-z}P_{z} layer, from the interface between a ground and the Ga₁₋ₓInₓN_{y}As_{1-y-z}Sb_{z} layer or the Ga₁₋ₓInₓN_{y}As_{1-y-z}Sb_{z} layer.

7. A semiconductor device according to claim 5, wherein a buffer layer of n-type semiconductor is provided between the InP substrate and the Ga₁₋ₓInₓN_{y}As_{1-y-z}Sb_{z} layer or the Ga₁₋ₓInₓN_{y}As_{1-y-z}P_{z} layer.

8. A semiconductor device according to claim 7, wherein the carrier concentration of the buffer layer is equal to 1×10¹⁶/cm³ or more.

9. A semiconductor device according to claim 5, wherein the semiconductor device is a photodiode.

10. A method of manufacturing an epitaxial wafer, comprising the steps of:
epitaxially growing a Ga₁₋ₓInₓN_{y}As_{1-y-z}Sb_{z} layer (0.4≦x≦0.8, 0<y≦0.1, 0≦z≦0.1) or a Ga₁₋ₓInₓN_{y}As_{1-y-z}P_{z} layer (0.4≦x≦0.8, 0<y≦0.1, 0≦z≦0.1) on an InP substrate by a molecular beam epitaxy (MBE) method; and
providing a heat treatment at a temperature in the range of 600° C. or more and less than 800° C. after the said step of epitaxial growth, wherein the average hydrogen concentration of the Ga₁₋ₓInₓN_{y}As_{1-y-z}Sb_{z} layer or the Ga₁₋ₓInₓN_{y}As_{1-y-z}P_{z} layer is made equal to 2×10¹⁷/cm³ or less.

11. An epitaxial wafer comprising an InP substrate and a Ga₁₋ₓInₓN_{y}As_{1-y-z}Sb_{z} layer (0.4≦x≦0.8, 0<y≦0.1, 0≦z≦0.1) or a Ga₁₋ₓInₓN_{y}As_{1-y-z}P_{z} layer (0.4≦x≦0.8, 0<y≦0.1, 0≦z≦0.1) formed by epitaxial growth on the InP substrate, wherein the average hydrogen concentration of the Ga₁₋ₓInₓN_{y}As_{1-y-z}Sb_{z} layer or the Ga₁₋ₓInₓN_{y}As_{1-y-z}P_{z} layer is equal to 2×10¹⁷/cm³ or less.

12. An epitaxial wafer comprising an InP substrate and a Ga₁₋ₓInₓN_{y}As_{1-y-z}Sb_{z} layer (0.4≦x≦0.8, 0<y≦0.1, 0≦z≦0.1) or a Ga₁₋ₓInₓN_{y}As_{1-y-z}P_{z} (0.4≦x≦0.8, 0<y≦0.1, 0≦z≦0.1) formed by epitaxial growth on the InP substrate, wherein a high-concentration hydrogen layer having a hydrogen concentration peak value of 2×10¹⁸/cm³ or less is provided within a range of 0.5 μm or less in thickness in the Ga₁₋ₓInₓN_{y}As_{1-y-z}Sbₓ layer or the Ga₁₋ₓInₓN_{y}As_{1-y-z}P_{z} layer, from the interface between a ground and the Ga₁₋ₓInₓN_{y}As_{1-y-z}Sb_{z} layer or the Ga₁₋ₓInₓN_{y}As_{1-y-z}P_{z} layer.
